(19) United States
(12) Patent Application Publication
(10) Pub. No.: US 2012/0038383 A1
(43) Pub. Date: Feb. 16, 2012

(54) DIRECT-DOCKING PROBING DEVICE

(76) Inventors: Chien-Chou WU, Hsinchu Hsiang (TW); Ming-Chi CHEN, Hsinchu Hsiang (TW); Tsung-Yi CHEN, Hsinchu Hsiang (TW); Chung-Che LI, Hsinchu Hsiang (TW)

(21) Appl. No.: 13/091,148

(22) Filed: Apr. 21, 2011

(30) Foreign Application Priority Data
Aug. 13, 2010 (TW) 099127029
Nov. 22, 2010 (CN) 201010552375.0

(51) Int. Cl. G01R 31/00

(52) U.S. Cl. 324/756.01

(57) ABSTRACT

A direct-docking probing device is provided. The probing device includes a probe interface board, a space transformer, a conductive elastic member, a fixing frame, and at least one vertical probe assembly. The space transformer includes a space transforming plate and a reinforcing plate, and the mechanical strength of the reinforcing plate is larger than that of the space transforming plate. The reinforcing plate is electrically connected with the space transforming plate. Furthermore, the conductive elastic member is electrically connected with the probe interface board and the reinforcing plate. The fixing frame includes a stiffener, a frame body, and a pressing portion. The stiffener is disposed on the probe interface board. The frame body contains the conductive elastic member. The pressing portion is pressed on the space transformer. The vertical probe assembly includes a plurality of vertical probes which are electrically connected with the space transforming plate.

### FIELD OF INVENTION

The invention relates to a probing device, especially relates to a probing device having a longer service life and a space transforming plate thereof to be less likely to be deformed.

### BACKGROUND OF THE INVENTION

Please refer to FIG. 1A and FIG. 1B. FIG. 1A shows a conventional probing system. FIG. 1B shows a probing device shown in FIG. 1A. The probing system 1000 includes a test head 1100, a conventional probing device 1200, and a prober 1400. The probing device 1200 includes a probe interface board 1210, a pogo tower 1220, and a probe card 1230. The probing device 1200 is mounted on the test head 1100. The test signals sent from the test head 1100 are passed through the probe interface board 1210, the pogo tower 1220, and the probe card 1230 in turn, and then transmitted into a device under test (DUT) 1300 via a plurality of vertical probes 1231 of the probe card 1230. Because the signal transmission path is of a relatively long distance, signal failure is possible to occur when a plurality of high-frequency test signals are transmitted.

To try to overcome the above described problems, person skilled in the art had provided another probing system and device. Please refer to FIG. 2 which shows another conventional probing system. A conventional probing device 10 includes a probe interface board 12, a space transforming plate 14, and a vertical probe assembly 19. The probe interface board 12 is electrically connected with the space transforming plate 14 via a plurality of solders. The vertical probe assembly 19 includes a guide plate 192 and a plurality of vertical probes 194. The guide plate 192 is mounted on the bottom surface of the space transforming plate 14. The vertical probes 194 are penetrated through the guide plate 192 and electrically connected with the space transforming plate 14.

The probing device 10 is a direct-docking probing device. No probe card is disposed in the probing device 10, so that the signal transmission path is shorter and the probing device 10 is suitable for carrying the high-frequency signals. In the probing device 10 (of direct-docking type), the probe interface board 12 is used to replace the circuit board of the probe card. Because the area of the probe interface board 12 is several times larger than that of the circuit board of the probe card, more electronic components can be mounted on the probe interface board 12. Therefore, the probe interface board 12 has improved test effectiveness and can detect more types of DUTs. In addition, due to having a larger area, the probe interface board 12 can be configured to test a larger number of DUTs at the same time.

Whether referring to the probing device 10 in FIG. 2 or the probing device 1200 in FIG. 1B, both probing devices 10, 1200, each of which requires to use a seating surface for a flatness standard. The flatness is defined as the difference between the maximum and minimum distances from the tip of the probe to the seating surface.

However, the probe interface board 12 and the space transforming plate 14 are connected together by reflowing. During the reflowing operation, the probe interface board 12 must sustain high temperature heating, so that the probe interface board 12 is possible to become damaged. In addition, the unit cost of the probe interface board 12 is higher due to having more electronic components disposed thereon, and the cost burden on the user is thereby increased.

In order to try to solve the above described problems, another conventional probing device 20 shown in FIG. 3 is provided. The probing device 20 includes a probe interface board 22, a space transforming plate 24, a fixing frame 25, a supporting plate 26, a plurality of electrical contacts 28, and a vertical probe assembly 29. The supporting plate 26 is disposed between the probe interface board 22 and the space transforming plate 24. The electrical contacts 28 are disposed in the supporting plate 26. The fixing frame 25 is mounted on the probe interface board 22. The pressing portion 251 of the fixing frame 25 is pressed on the space transforming plate 24, in order to ensure adequate electrical conductivity between the electrical contacts 28 and the space transforming plate 24. The electrical contacts 28 and the probe interface board 22 are connected without the reflowing operation, so that the probe interface board 22 does not require sustaining higher temperature heating, and thus the probe interface board 22 has longer service life.

In today's industry; the space transforming plate 24 is made by the back-end-of-line (BEOL) semiconductor manufacturing process, i.e. packaging process, so that the thickness of the space transforming plate 24 has become thinner. However, the height from the bottom surface of the probe interface board 22 to the tip of the vertical probe assembly 29 is limited by the usage environment; thus, such height is harder to be adjusted when the space transforming plate 24 becomes thinner. Taiwan patent publication number 201003078 discloses a thickening plate. The thickening plate, disposed between the electrical contacts and the space transforming plate, can solve the problems caused by the thinner space transforming plate. However, the thickening plate is mainly used in the vertical probe card instead of the direct-docking probing system.

Furthermore, the area of the space transforming plate 24 becomes larger due to the corresponding larger area of the probe interface board 22. Because of the thinner thickness and the larger area of the space transforming plate 24, the space transforming plate 24 will have larger deformation when the electrical contacts 28 apply an elastic force on it. Therefore, the probes of the vertical probe assembly 29 cannot accurately be contacted with the device under test. In addition, when the vertical probe assembly 29 is contacted with the device under test, the device under test will apply a reaction force back to the vertical probe assembly 29, so as to deflect the space transforming plate 24 toward the probe interface board 22, thus compressing and damaging the electrical contacts 28.

Hence, there is a need in the art for preventing the space transforming plate from being deflected in the direct-docking probing device.

### SUMMARY OF THE INVENTION

One aspect of the invention is to provide a direct-docking probing device. The direct-docking probing device can prevent the space transforming plate from being deflected.

To achieve the foregoing and other aspects, a direct-docking probing device is provided. The probing device includes a probe interface board, a space transformer, a conductive elastic member, a fixing frame, and at least one vertical probe assembly. The space transformer includes a space transforming plate and a reinforcing plate. The reinforcing plate is disposed between the probe interface board and the space transforming plate, and a plurality of circuits is disposed in the reinforcing plate. The reinforcing plate is electrically connected with the space transforming plate by a plurality of solders. The mechanical strength of the reinforcing plate is larger than that of the space transforming plate. Furthermore, the conductive elastic member is located between the reinforcing plate and the probe interface board, and electrically connected with the probe interface board and the reinforcing plate. The fixing frame includes a stiffener, a frame body, and a pressing portion. The stiffener is disposed on the probe interface board. The frame body contains the conductive elastic member. The pressing portion is pressed on the space transformer. The vertical probe assembly includes a plurality of vertical probes which are electrically connected with the space transforming plate.

In the probing device, the pressing portion is pressed on the reinforcing plate.

In the probing device, the pressing portion is pressed on the space transforming plate.

In the probing device, the reinforcing plate is a multilayer ceramic structure, and the space transforming plate is a multilayer organic structure. The thickness of the space transforming plate is smaller than 1.8 mm and the thickness of the reinforcing plate is larger than 1.0 mm. In addition, the thickness of the space transforming plate is preferably smaller than 1.5 mm and the thickness of the reinforcing plate is preferably larger than 1.5 mm.

In the probing device, the solders are surrounded by a filler layer, and the material of the filler layer is a polymer.

In the probing device, the Young's modulus of the space transforming plate is 11 Gpa and the Young's modulus of the reinforcing plate is 120 Gpa.

In the probing device, the conductive elastic member comprises a supporting plate and a plurality of electrical contacts. The electrical contacts are penetrated through and fixed by the supporting plate; and the electrical contacts possess elasticity.

In addition, the probing device further comprises a protective device. Compared with respect to the pressing portion of the fixing frame, the protective device is pressed on the other side of the space transformer.

In the probing device, the protective device comprises at least two protective spacers. The two ends of the protective spacers are pressed on the probe interface board and the reinforcing plate, respectively.

In the probing device, the protective device comprises at least two protective screws. The protective screws are penetrated through the probe interface board, and the bottom ends of the protective screws are pressed on the reinforcing plate.

In the probing device, the protective device comprises a limit portion. The limit portion is formed on the frame body and pressed on the reinforcing plate.

The protective device comprises a protective frame. The protective frame comprises a hollow portion; and the hollow portion is used for containing the conductive elastic member. The two ends of the protective frame are pressed on the probe interface board and the reinforcing plate, respectively.

In the probing device, the protective device is located around the periphery of the conductive elastic member.

In the probing device, the electrical circuits in the reinforcing plate are vertically penetrated through the reinforcing plate.

In the probing device, the frame body and the pressing portion are formed integrally.

The probing device further comprises a protective screw. The protective screw is penetrated through the center portion of the probe interface board and the center portion of the conductive elastic member. The bottom end of the protective screw is pressed on the reinforcing plate.

In the probing device, the protective device comprises a protective film, and the conductive elastic member comprises a supporting plate and a plurality of electrical contacts. The electrical contacts are penetrated through the supporting plate and are supported by the supporting plate, and the electrical contacts possess elasticity. The protective film is located between the supporting plate and the reinforcing plate or between the supporting plate and the probe interface board. A plurality of through holes, through which the electrical contacts are penetrated, is formed in the protective film.

In the probing device, the quantity of the space transforming plates and the vertical probe assemblies are both numerous, i.e. more than one. Each vertical probe assembly is individually electrically connected to one of the space transforming plates, respectively.

Because the mechanical strength of the reinforcing plate is larger than that of the space transforming plate, the amount of deformation of the reinforcing plate is smaller than that of the space transforming plate. Therefore, the offset amount of the vertical probe assembly is small, so that the vertical probes can be more accurately contacted with the device under test.

### BRIEF DESCRIPTION OF THE DRAWINGS

FIG. 1A shows a conventional probing system.

FIG. 1B shows a probing device shown in FIG. 1A.

FIG. 2 shows another conventional probing system.

FIG. 3 shows yet another conventional probing system.

FIG. 4A shows a probing system of a first embodiment in the present invention.

FIG. 4B shows a probing device of the first embodiment in the present invention.

FIG. 4C shows a probing device of a second embodiment in the present invention.

FIG. 5 shows a probing device of a third embodiment in the present invention.

FIG. 6 shows a probing device of a fourth embodiment in the present invention.

FIG. 7 shows a probing device of a fifth embodiment in the present invention.

FIG. 8 shows a probing device of a sixth embodiment in the present invention.

FIG. 9 shows a probing device of a seventh embodiment in the present invention.

FIG. 10 shows a probing device of an eighth embodiment in the present invention.

### DETAILED DESCRIPTION OF THE INVENTION

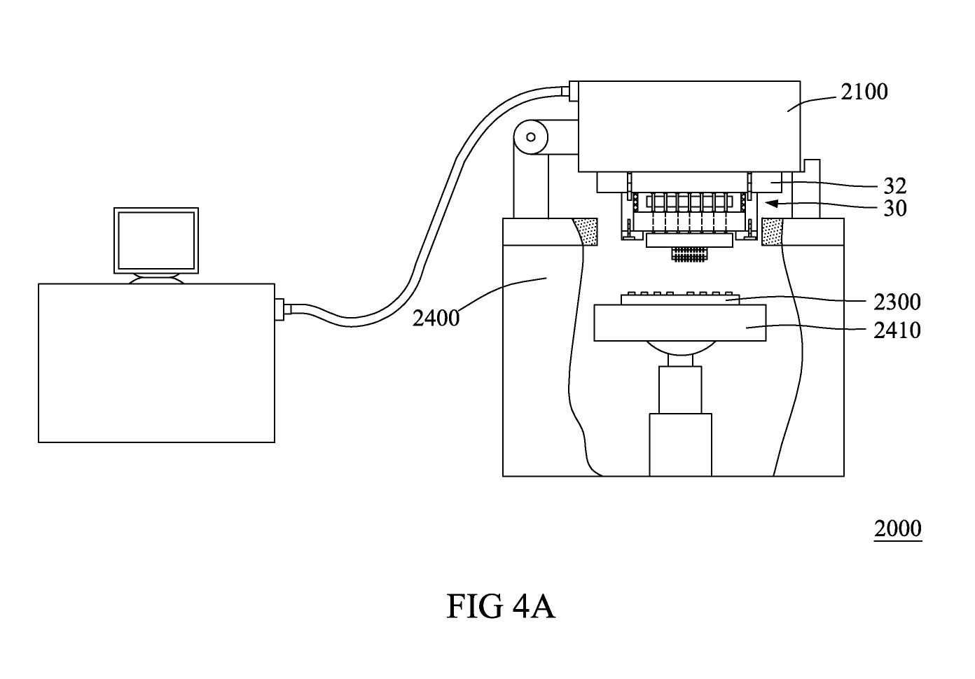

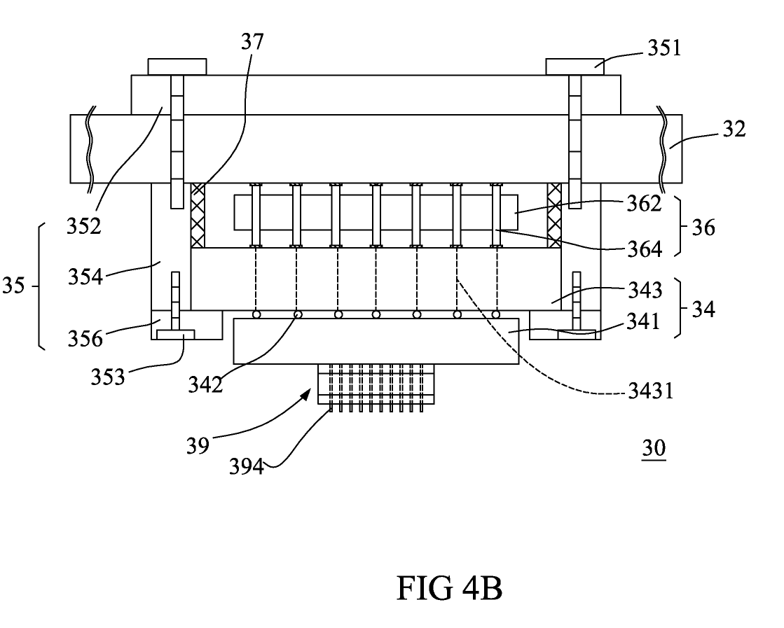

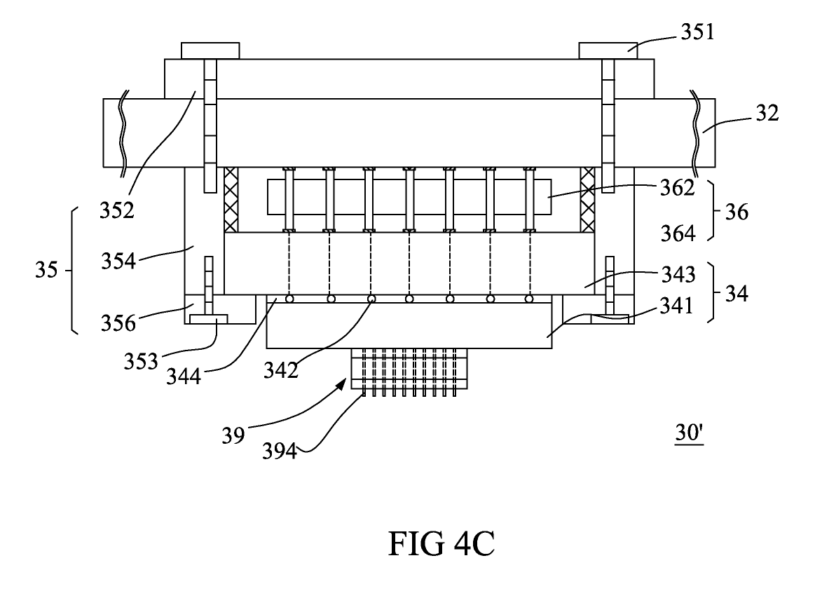

Please refer to FIG. 4A and FIG. 4B. FIG. 4A shows a probing system of a first embodiment in the present invention. FIG. 4B shows a probing device 30 of the first embodiment in the present invention. The probing device 30 is, for example, mounted on the probing system 2000. The probing system 2000 includes a test head 2100, the probing device 30, and a prober 2400. The prober 2400 includes a wafer stage 2410. A device under test 2300 is disposed on the wafer stage 2410. The probing device 30 includes a probe interface board 32, a space transformer 34, a fixing frame 35, a conductive elastic member 36, two protective spacers 37, and a vertical probe assembly 39.

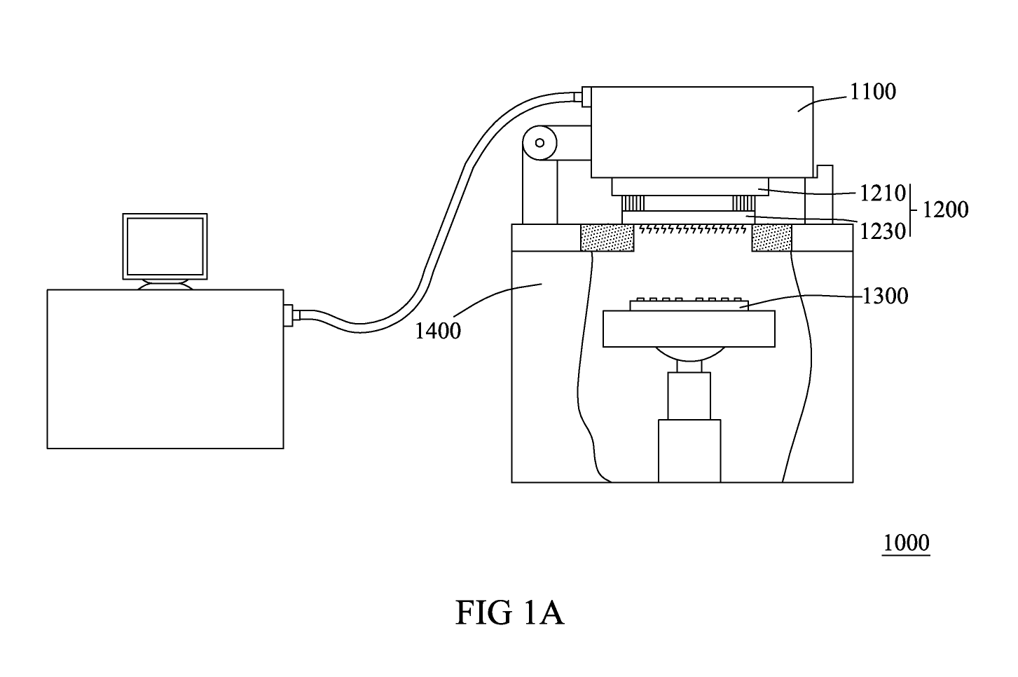

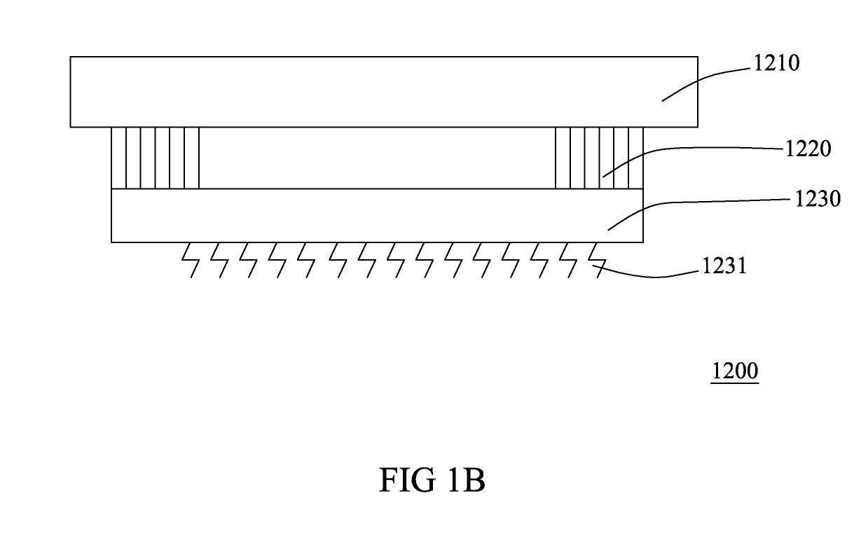

Please refer to FIG. 1A and FIG. 4A. In FIG. 1A the probe card 1230 of the probing device 1200 is configured to be set downward. The seating surface for the probe card 1230 is formed on the prober 1400. In FIG. 4A, the probing device 30 is connected with the test head 2100. In other words, the probe interface board 32 of the probing device 30 is set in an upward configuration. The seating surface for the probe interface board 32 is formed on the test head 2100, i.e. the probe interface board 32 is connected with the test head 2100.

Please refer to FIG. 4B. The space transformer 34 includes a space transforming plate 341 and a reinforcing plate 343. The reinforcing plate 343 is located between the probe interface board 32 and the space transforming plate 341. The reinforcing plate 343 is electrically connected with the space transforming plate 341 via a plurality of solders 342. Furthermore, the mechanical strength of the reinforcing plate 343 is larger than that of the space transforming plate 341. Because of the presence and usage of the reinforcing plate 343 in the space transformer 34, the overall mechanical strength of the space transformer 34 is increased.

The conductive elastic member 36 is located between the reinforcing plate 343 and the probe interface board 32. In the embodiment, the conductive elastic member 36 includes a supporting plate 362 and a plurality of electrical contacts 364. The electrical contacts 364 possess elasticity, and are penetrated through and supported by the supporting plate 362. Furthermore, a plurality of circuits 3431 is disposed in the reinforcing plate 343. Therefore, after passing through the electrical contacts 364, the test signals sent from the probe interface board 32 is then passed through the circuits 3431 in the reinforcing plate 343 and transferred into the space transforming plate 341.

The fixing frame 35 includes a stiffener 352, a body frame 354, and a pressing portion 356. The stiffener 352 is disposed on one side of the probe interface board 32, and by using two locking screws 353, the body frame 354 can be screwed on the other side of the probe interface board 32. The body frame 354 contains the reinforcing plate 343 and the conductive elastic member 36. The pressing portion 356 is locked on the body frame 354 by the two locking screws 353. The pressing portion 356 is pressed on one side of the reinforcing plate 343, in order to ensure adequate electrical conductivity between the electrical contacts 364 and the space transforming plate 343. Although the body frame 354 and the pressing portion 356 are of two different elements, the body frame 354 and the pressing portion 356 can be formed integrally, so that the locking screws 353 are no longer needed. In addition, the electrical conductivity between the electrical contacts 364 and the reinforcing plate 343 can be enhanced by screwing the locking screws 351 more tightly.

Furthermore, the protective spacer 37 is disposed between the reinforcing plate 343 and the probe interface board 32, and located around the periphery of the conductive elastic member 36. The two protective spacers 37 are each located on the two opposite sides, respectively. The top ends of the protective spacers 37 are pressed against the probe interface board 32 and the bottom ends of the protective spacers 37 are pressed on the reinforcing plate 343. Compared with respect to the pressing portion 356, the protective spacers 37 are pressed on the other side of the reinforcing plate 343.

Please refer to FIG. 4A. The vertical probe assembly 39 includes a plurality of vertical probes 394. The vertical probes 394 are electrically connected with the space transforming plate 341. The bottom of the vertical probes 394 are contacted with the device under test (not shown).

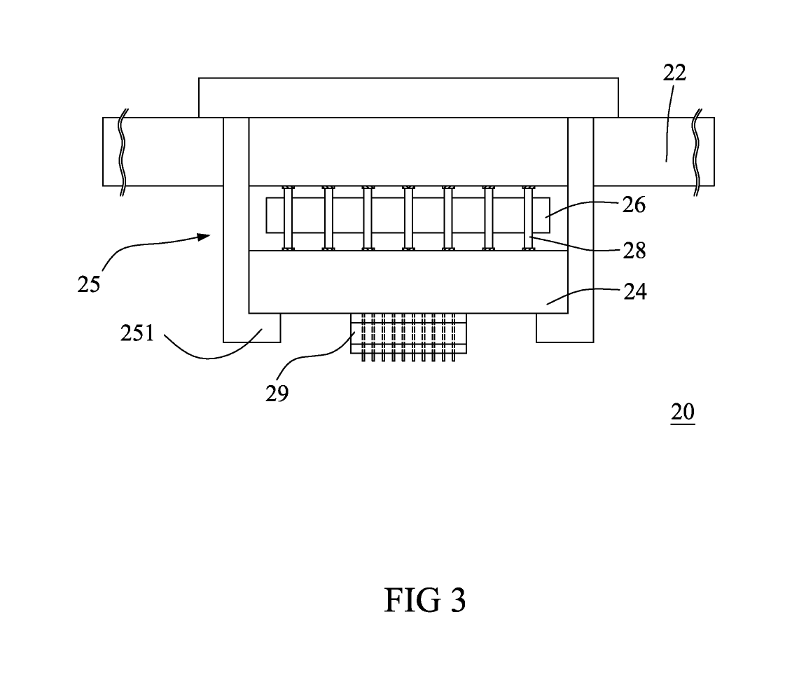

In the embodiment, the Young's module of the space transforming plate 341 is 11 Gpa, and the Young's module of the reinforcing plate 343 is 120 Gpa. Because the mechanical strength of the reinforcing plate 343 is larger than that of the space transforming plate 341, the amount of deformation of the space transforming plate 341 is smaller than that of the space transforming plate 24 in FIG. 3. Therefore, compared to the vertical probe assembly 29 in FIG. 3, the offset amount of the vertical probe assembly 39 is smaller, so that the vertical probes 394 can be more accurately contacted with the device under test (not shown).

In addition, when the vertical probe 394 is contacted with the device under test, the device under test will apply a reaction force back to the vertical probe 394. At the same time, because of the support of the protective spacer 37, the space transformer 34 is not easily deflected toward the probe interface board 32. Thus, the electrical contacts 364 are not easily compressed and are thereby better protected.

In the embodiment, the reinforcing plate 343 is a multilayer ceramic structure, and the space transforming plate 341 is a multilayer organic structure. Person of ordinary skill in the art can modify the material and the structure of the reinforcing plate 343 or the space transforming plate 341, provided that the mechanical strength of the reinforcing plate 343 is larger than that of the space transforming plate 341, so as to prevent any large amount of deformation from occurring on the space transforming plate 341. The reinforcing plate 343 can also be made as a multilayer organic structure, a printed circuit board structure, or a FR-4 type glass fiber board.

In this embodiment, the thickness of the space transforming plate 341 is smaller than 1.8 mm, and the thickness of the reinforcing plate 343 is larger than 1.0 mm. In a preferred embodiment, the thickness of the space transforming plate 341 is smaller than 1.5 mm, and the thickness of the reinforcing plate 343 is larger than 1.5 mm.

Please refer to FIG. 4C which shows a probing device 30′ of a second embodiment in the present invention. In the probing device 30′, the solders 342 are surrounded by a filler layer 344, and the filler layer 344 is made of polymer material. The filler layer 344 is used to prevent the solders 342 from being polluted by the external environment. Because the other elements of the probing device 30′ is identical or similar to the elements shown in FIG. 4B, they are marked with the same numbers in FIG. 4C and not described in detail.

Person of ordinary skill in the art can use other protective device to replace the protective spacer 37, for example: a protective frame. The protective frame is a hollow plate-shaped object and is located around the conductive elastic member 36. The hollow portion of the protective frame is used to contain the conductive elastic member 36. The two ends of the protective frame are pressed on the probe interface board 32 and the reinforcing plate 343, respectively.

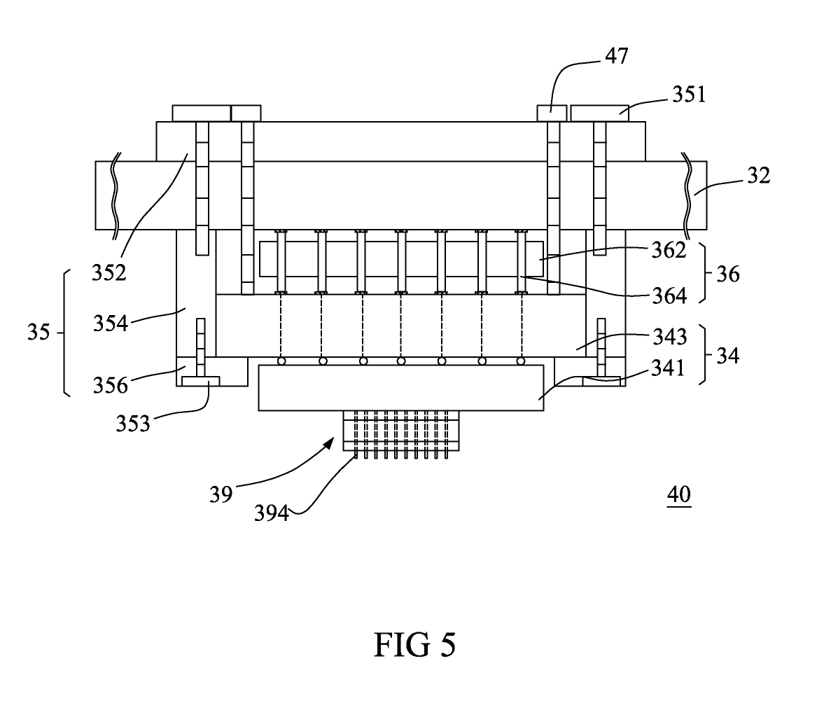

Please refer to FIG. 5 which shows a probing device 40 of a third embodiment in the present invention. The probing device 40 includes two protective screws 47. The protective screws 47 are penetrated through the probe interface board 32, and the bottom ends of the protective screws 47 are pressed on the reinforcing plate 343. The protective screws 47 and the protective spacer 37 have a similar function, i.e. preventing the space transformer 34 from being deflected toward the probe interface board 32, so as to avoid the electrical contacts 364 being compressed and damaged.

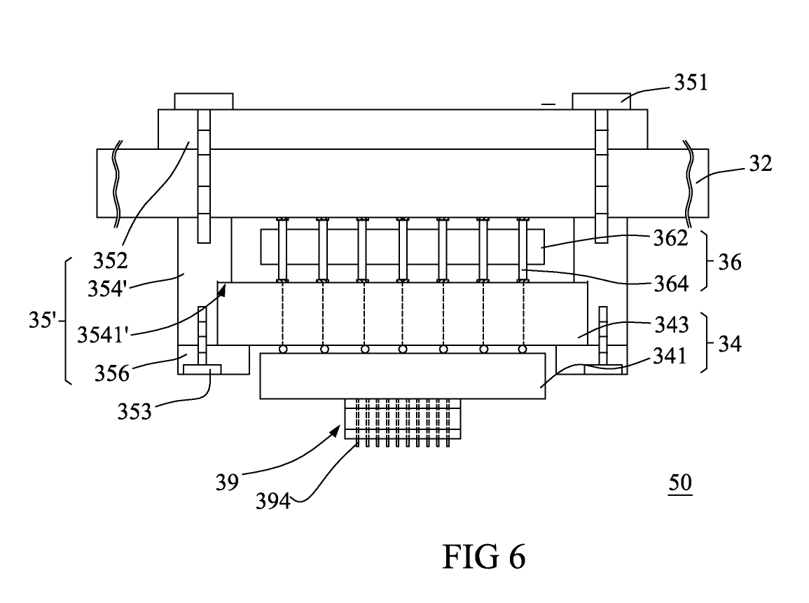

Please refer to FIG. 6 which shows a probing device 50 of a fourth embodiment in the present invention. In the probing device 50, a limit portion 3541′ is formed on the body frame 354′ of the fixing frame 35′. Compared with respect to the pressing portion 356, the limit portion 3541′ is pressed on the other side of the reinforcing plate 343. In other words, the reinforcing plate 343 is clamped by the pressing portion 356 and the limit portion 3541′. Because of the limit portion 3541′, the deformation of the space transformer 34 caused by the reaction force from the device under test can be avoided. In addition, the limit portion 3541′ can prevent the transformer 34 from being deflected toward the probe interface board 32 and protect the electrical contacts 364 from being compressed and damaged, so that the limit portion 3541′ can be a protective device for the probing device 50.

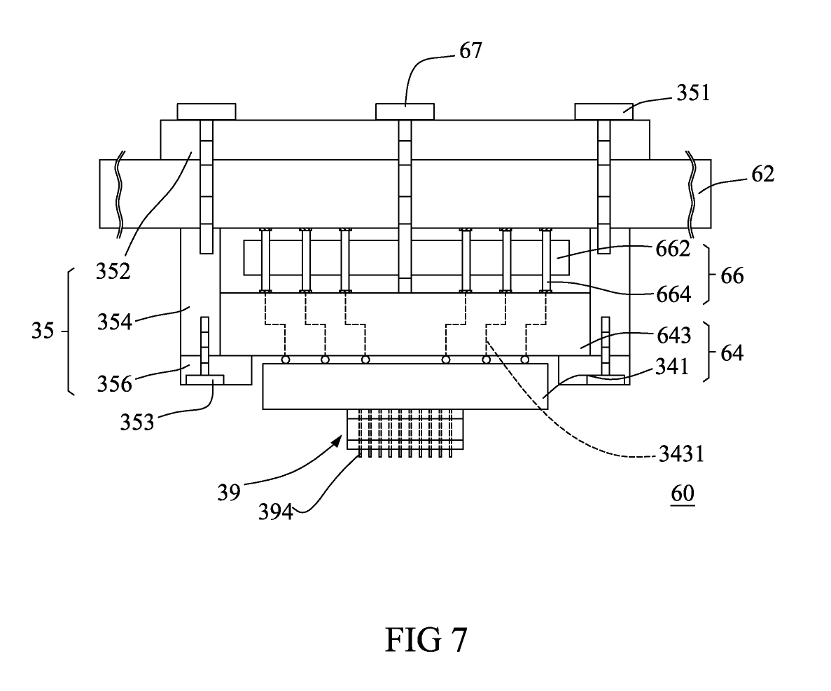

Please refer to FIG. 7 which shows a probing device 60 of a fifth embodiment in the present invention. The probing device 60 includes a protective screw 67. The protective screw 67 is penetrated through the center portion of a probe interface board 62 and the center portion of a supporting plate 662 of the conductive elastic member 66. The bottom end of the protective screw 67 is pressed on the reinforcing plate 643. In another embodiment, a threaded hole (not shown) can be formed in the reinforcing plate 643, and the bottom end of the protective screw 67 can be screwed with the threaded hole. If the reinforcing plate 643 is made of ceramic material and not easily to be threaded, a metal block having an inner thread can be embedded in the reinforcing plate 643, so as to lock the bottom end of the protective screw 67 and the reinforcing plate 643 together. When the vertical probe 394 is contacted with the device under test, the device under test will apply a reaction force back. At this time, because the bottom end of the protective screw 67 is pressed on the reinforcing plate 643, the deflection of a space transformer 64 toward the probe interface board 62 can be avoided.

In FIG. 4A, the circuits 3431 is penetrated through the reinforcing plate 343 vertically. However, in the probing device 60 shown in FIG. 7, the protective screw 67 is penetrated through the central portion of the conductive elastic member 66, so that the electrical contacts 664 would be configured to be disposed in locations toward the respective two sides. Therefore, the circuits 6431 in the reinforcing plate 643 have a deflecting part, in order to ensure adequate electrical connection between the space transformer 64 and the reinforcing plate 643. Furthermore, in order to better protect the electrical contacts 664, other protective devices, such as the protective device shown in FIG. 4A˜FIG 6, can be disposed around the conductive elastic member 66 shown in FIG. 7.

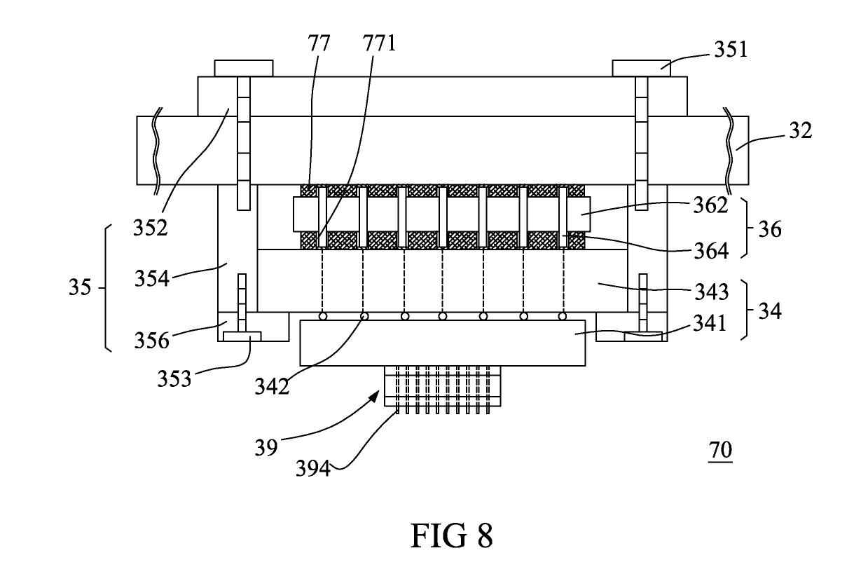

Please refer to FIG. 8 which shows a probing device 70 of a sixth embodiment in the present invention. In this embodiment, the protective device of the probing device 70 includes two protective films 77. One of the protective films 77 is disposed between the supporting plate 362 and the reinforcing plate 343, and another protective film 77 is disposed between the supporting plate 362 and the probe interface board 32. The protective film 77 has a plurality of through holes 771 and the electrical contacts 364 are penetrated through the through holes 771. Person of ordinary skill in the art can also choose to dispose only one protective film 77 in the probing device 70, and the protective film 77 is disposed between the supporting plate 362 and the reinforcing plate 343 or between the supporting plate 362 and the probe interface board 32.

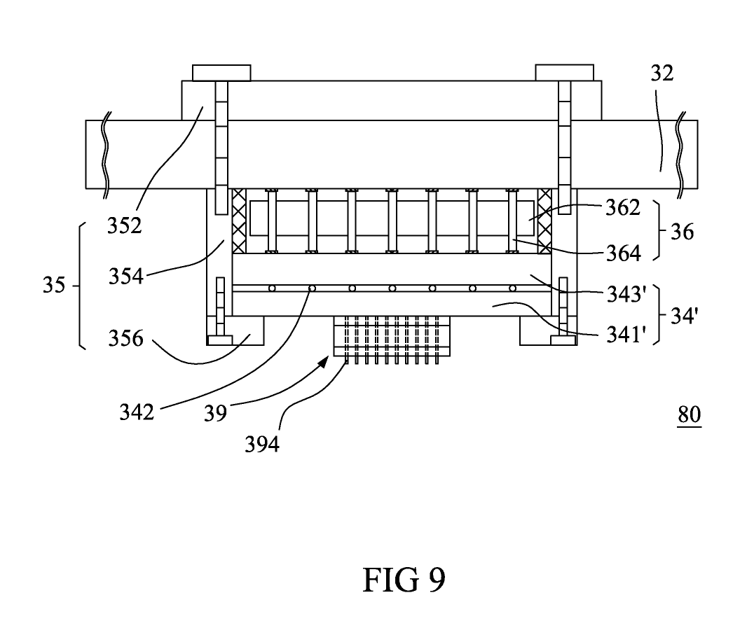

In the above described embodiments, the reinforcing plate 343 is disposed in the fixing frame 35, and the space transforming plate 341 is disposed outside of the fixing frame 35. Please refer to FIG. 9, which shows a probing device 80 of a seventh embodiment in the present invention. In the probing device 80, a reinforcing plate 343′ of a space transformer 34′ and a space transforming plate 341′ are both disposed in the frame body 354 of the fixing frame 35. Furthermore, the pressing portion 356 of the fixing frame 35 is pressed on the space transforming plate 341′.

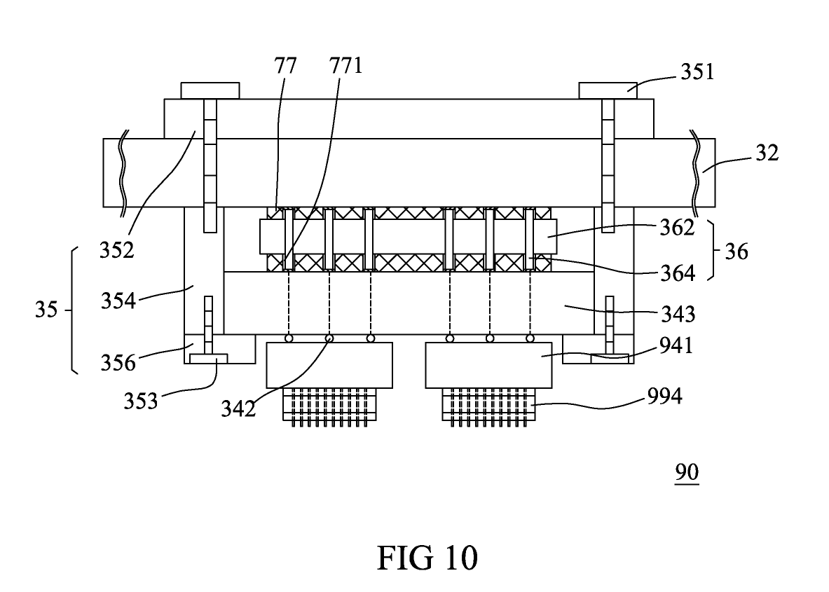

Please refer to FIG. 10, which shows a probing device 90 of an eighth embodiment in the present invention. In the probing device 90, two space transforming plates 941 are disposed, and two vertical probe assemblies 994 are each mounted on the bottom ends of the two space transforming plates 941, respectively. Thus the probing device 90 can probe two devices under test at the same time. The surfaces of the probe interface board 32 and the reinforcing plate 343 can be enlarged depending on the requirement conditions, therefore more space transforming plates and vertical probe assemblies can be mounted thereon, so as to probe more than one device under test at the same time.

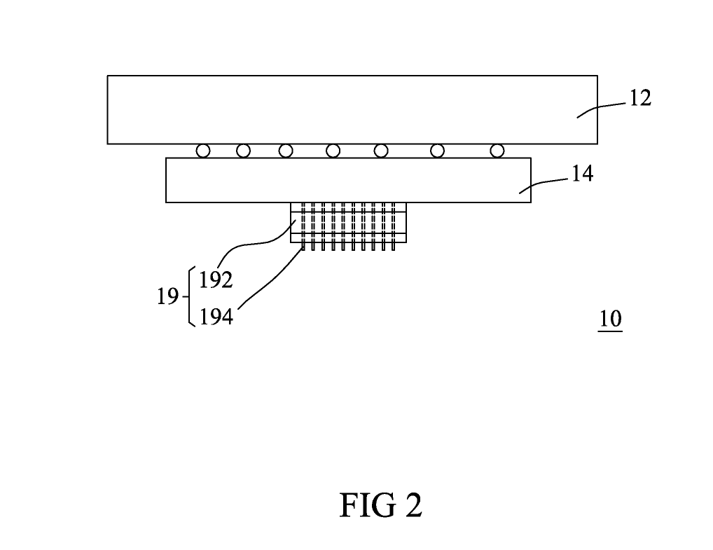

In all of the embodiments discussed above, the electrical contacts are used to electrically connect the reinforcing plate and the probe interface board, and prevent the probe interface board from being processed under the reflow operation, so as to increase the service life of the probe interface board. The electrical contacts can be designed to be in the form such as the signal contacts shown in FIG. 1 and FIG. 2 of U.S. Pat. No. 6,722,893, the electrical contacts shown in FIG. 3 and FIG. 4 of U.S. Pat. No. 6,846,184, or the elastomeric contacts shown in FIG. 1 and FIG. 2 of U.S. Pat. No. 6,712,620. The electrical contacts can be mainly comprised of the anisotropic conductive paste.

In the above described embodiments, the probing devices are all equipped with the protective devices. However, Person of ordinary skill in the art can opt to design a probing device having no protective device.

Although the description above contains many specifics, these are merely provided to illustrate the invention and should not be construed as limitations of the invention's scope. Thus it will be apparent to those skilled, in the art that various modifications and variations can be made in the system and processes of the present invention without departing from the spirit or scope of the invention.

What is claimed is:

1. A direct-docking probing device, comprising:
a probe interface board;
a space transformer, the space transformer comprising a space transforming plate and a reinforcing plate, the reinforcing plate located between the probe interface board and the space transforming plate, a plurality of circuits disposed in the reinforcing plate, the reinforcing plate electrically connected with the space transforming plate by a plurality of solders, and the mechanical strength of the reinforcing plate being larger than the mechanical strength of the space transforming plate;
a conductive elastic member, the conductive elastic member located between the reinforcing plate and the probe interface board, and the conductive elastic member electrically connected with the probe interface board and the reinforcing plate;
a fixing frame, the fixing frame comprising a stiffener, a frame body, and a pressing portion, the stiffener disposed on the probe interface board, the conductive elastic member contained in the frame body, and the pressing portion pressed on the space transformer; and
at least one vertical probe assembly, the vertical probe assembly includes a plurality of vertical probes, and the vertical probes are electrically connected with the space transformer.

2. The probing device of claim 1, wherein the pressing portion is pressed on the reinforcing plate.

3. The probing device of claim 1, wherein the pressing portion is pressed on the space transforming plate.

4. The probing device of claim 1, wherein the reinforcing plate is a multilayer ceramic structure, and the space transforming plate is a multilayer organic structure.

5. The probing device of claim 4, wherein the thickness of the space transforming plate is smaller than 1.8 mm and the thickness of the reinforcing plate is larger than 1.0 mm.

6. The probing device of claim 5, wherein the thickness of the space transforming plate is smaller than 1.5 mm and the thickness of the reinforcing plate is larger than 1.5 mm.

7. The probing device of claim 1, wherein the solders, which are located between the reinforcing plate and the space transforming plate, are surrounded by a filler layer, and the material of the filler layer is polymer.

8. The probing device of claim 1, wherein the Young's modulus of the space transforming plate is 11 Gpa and the Young's modulus of the reinforcing plate is 120 Gpa.

9. The probing device of claim 1, wherein the conductive elastic member comprises a supporting plate and a plurality of electrical contacts, the electrical contacts are penetrated through the supporting plate and fixed by the supporting plate, and the electrical contacts possess elasticity.

10. The probing device of claim 1, further comprising a protective device, wherein compared with respect to the pressing portion of the fixing frame, the protective device is pressed on the other side of the space transformer.

11. The probing device of claim 10, wherein the protective device comprises at least two protective spacers, and two ends of the protective spacers are pressed on the probe interface board and the reinforcing plate, respectively.

12. The probing device of claim 10, wherein the protective device comprises at least two protective screws, the protective screws are penetrated through the probe interface board, and the bottom ends of the protective screws are pressed on the reinforcing plate.

13. The probing device of claim 10, wherein the protective device comprises a limit portion, and the limit portion is formed on the frame body and pressed on the reinforcing plate.

14. The probing device of claim 10, wherein the protective device comprises a protective frame, the protective frame comprises a hollow portion, the hollow portion is used for containing the conductive elastic member, and two ends of the protective frame are pressed on the probe interface board and the reinforcing plate, respectively.

15. The probing device of claim 10, wherein the protective device is located around the periphery of the conductive elastic member.

16. The probing device of claim 1, wherein the circuits in the reinforcing plate are vertically penetrated through the reinforcing plate.

17. The probing device of claim 1, wherein the frame body and the pressing portion are formed integrally.

18. The probing device of claim 1, further comprising a protective screw, wherein the protective screw is penetrated through the center portion of the probe interface board and the center portion of the conductive elastic member, and the bottom end of the protective screw is pressed on the reinforcing plate.

19. The probing device of claim 10, wherein the protective device comprises a protective film, and the conductive elastic member comprises a supporting plate and a plurality of electrical contacts, the electrical contacts are penetrated through the supporting plate and supported by the supporting plate, the electrical contacts possess elasticity, the protective film is located between the supporting plate and the reinforcing plate or between the supporting plate and the probe interface board, and a plurality of through holes, through which the electrical contacts are penetrated, is formed in the protective film.

20. The probing device of claim 1, wherein the quantity of the space transforming plates and the vertical probe assemblies are both more than one, and each vertical probe assembly is individually electrically connected to one of the space transforming plates, respectively.
